(19) United States
(12) Patent Application Publication
(10) Pub. No.: US 2026/0123295 A1
(43) Pub. Date: Apr. 30, 2026

(54) RESISTIVE MEMORY STRUCTURE AND FABRICATION METHOD THEREOF

(71) Applicant: UNITED MICROELECTRONICS CORP., Hsin-Chu City (TW)

(72) Inventors: Yu-Sheng Cheng, Kaohsiung City (TW); Yu-Wei Lin, Singapore (SG); Yuan Zhou, Singapore (SG); Jian Shi, Singapore (SG)

(73) Assignee: UNITED MICROELECTRONICS CORP., Hsin-Chu City (TW)

(21) Appl. No.: 18/946,796

(22) Filed: Nov. 13, 2024

(30) Foreign Application Priority Data
Oct. 24, 2024 (TW) 113140601

(51) Int. Cl. H10N 70/00; H10B 63/00; H10N 70/20

(52) U.S. Cl. CPC H10N 70/8265; H10B 63/80; H10N 70/011; H10N 70/24; H10N 70/841; H10N 70/8833

(57) ABSTRACT

A resistive memory structure includes a substrate and a memory stack structure disposed on the substrate. The memory stack structure includes a bottom electrode layer, a switching layer disposed on the bottom electrode layer, a top electrode layer disposed on the switching layer, and an oxidized protection layer disposed on a sidewall of the memory stack structure. A spacer is located around the memory stack structure. The spacer covers the oxidized protection layer. A dielectric buffer layer is disposed on the spacer.

### BACKGROUND OF THE INVENTION

### 1. Field of the Invention

The present invention relates to the field of semiconductor technology, and in particular to an improved resistive memory structure and a manufacturing method thereof.

### 2. Description of the Prior Art

Resistive random-access memory (RRAM) cells typically consist of two conductive electrodes sandwiching a switching layer, which allows the memory cell to switch between a high-resistance state (HRS), representing a logical “0,” and a low-resistance state (LRS), representing a logical “1.”

RRAM operation relies on the formation and breaking of conductive filaments within the switching layer. These filaments create low-resistance paths between the electrodes, driving the cell to the LRS. However, the unpredictable number and distribution of these filaments lead to unstable electrical characteristics, such as variations in the voltages required to set (switch to LRS) or reset (switch to HRS) the cell.

Furthermore, when depositing the ultra-low-k dielectric layer (ULK), the arcing phenomenon generated in the plasma chemical vapor deposition process will cause damage to the RRAM memory structure. Therefore, further efforts need to be made to overcome this problem.

### SUMMARY OF THE INVENTION

It is one object of the present invention to provide an improved resistive memory structure and a manufacturing method thereof to solve the deficiencies or shortcomings of the existing technology.

One aspect of the invention provides a resistive memory structure including a substrate; a memory stack structure disposed on the substrate, wherein the memory stack structure includes a bottom electrode layer, a switching layer disposed on the bottom electrode layer, a top electrode layer disposed on the switching layer, and an oxidized protection layer disposed on a sidewall of the memory stack structure; a spacer located around the memory stack structure, wherein the spacer covers the oxidized protection layer; and a dielectric buffer layer disposed on the spacer.

According to some embodiments, the resistive memory structure further includes an inter-metal dielectric (IMD) layer covering the dielectric buffer layer.

According to some embodiments, the resistive memory structure further includes a conductive via disposed on the memory stack structure in the IMD layer, wherein the conductive via is in direct contact with the top electrode layer, the spacer, and the dielectric buffer layer.

According to some embodiments, the top electrode layer includes a TaN layer and a TaNOₓ layer, wherein the TaNOₓ layer is in direct contact with the conductive via.

According to some embodiments, the conductive via includes a barrier layer and a copper layer.

According to some embodiments, the spacer is a silicon nitride spacer.

According to some embodiments, the dielectric buffer layer is a silicon oxide layer.

According to some embodiments, the silicon oxide layer is a PECVD oxide layer or a TEOS-based silicon oxide layer.

According to some embodiments, the switching layer includes a TaOₓ layer and a Ta₂O₅ layer, and wherein the bottom electrode layer includes a TaN layer.

According to some embodiments, the memory stack structure further includes an iridium layer between the switching layer and the top electrode layer.

Another aspect of the invention provides a method for forming a resistive memory structure. A substrate is provided. A memory stack structure is formed on the substrate. The memory stack structure includes a bottom electrode layer, a switching layer disposed on the bottom electrode layer, a top electrode layer disposed on the switching layer, and an oxidized protection layer disposed on a sidewall of the memory stack structure. A spacer is formed around the memory stack structure. The spacer covers the oxidized protection layer. A dielectric buffer layer is formed on the spacer.

According to some embodiments, the method further includes the step of forming an inter-metal dielectric (IMD) layer covering the dielectric buffer layer.

According to some embodiments, the method further includes the step of forming a conductive via on the memory stack structure in the IMD layer. The conductive via is in direct contact with the top electrode layer, the spacer, and the dielectric buffer layer.

According to some embodiments, the top electrode layer includes a TaN layer and a TaNOₓ layer, wherein the TaNOₓ layer is in direct contact with the conductive via.

According to some embodiments, the conductive via includes a barrier layer and a copper layer.

According to some embodiments, the spacer is a silicon nitride spacer.

According to some embodiments, the dielectric buffer layer is a silicon oxide layer.

According to some embodiments, the silicon oxide layer is a PECVD oxide layer or a TEOS-based silicon oxide layer.

According to some embodiments, the switching layer includes a TaOₓ layer and a Ta₂O₅ layer, and wherein the bottom electrode layer includes a TaN layer.

According to some embodiments, the memory stack structure further includes an iridium layer between the switching layer and the top electrode layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic diagrams showing a method of forming a resistive memory structure according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

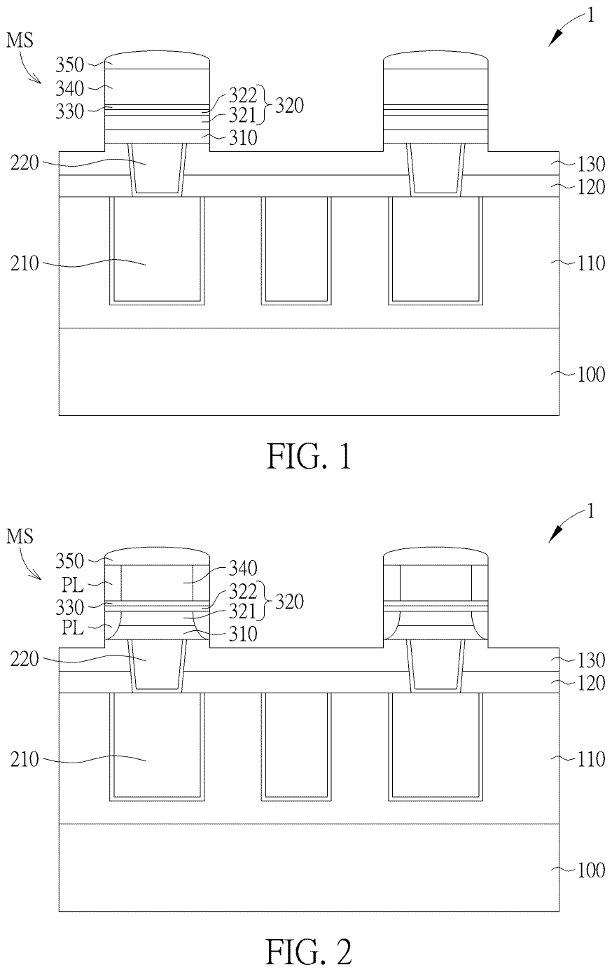

Please refer to FIG. 1 to FIG. 5, which are schematic diagrams showing a method of forming a resistive memory structure 1 according to an embodiment of the present invention. As shown in FIG. 1, a substrate 100 is first provided. For example, the substrate 100 may be a silicon substrate, but is not limited thereto. An inter-metal dielectric (IMD) layer 110, a capping layer 120 and a silicon oxide layer 130 are deposited on the substrate 100. According to an embodiment of the present invention, for example, the IMD layer 110 may include a low dielectric constant material or an ultra-low dielectric constant material. According to an embodiment of the present invention, for example, the capping layer 120 may include nitrogen-doped silicon carbide, with a thickness of, for example, 300-400 angstroms. According to an embodiment of the present invention, for example, the silicon oxide layer 130 may be formed by a plasma enhanced chemical vapor deposition (PECVD) process (also referred to as PECVD oxide layer), and its thickness is, for example, 400-800 angstroms.

According to an embodiment of the present invention, a lower metal conductor layer 210 is formed in the IMD layer 110. According to an embodiment of the present invention, for example, the lower metal conductor layer 210 may include copper, titanium nitride, titanium, tantalum nitride, or tantalum, but is not limited thereto. According to an embodiment of the present invention, for example, the lower metal conductor layer 210 may be formed using a copper damascene process. According to an embodiment of the present invention, a short via 220 may be formed in the capping layer 120 and the silicon oxide layer 130. According to an embodiment of the present invention, for example, the short via 220 may include tungsten, but is not limited thereto.

According to the embodiment of the present invention, a deposition process, a photolithography process, and an etching process are then performed to form a memory stack structure MS on the short via 220 and the silicon oxide layer 130. According to an embodiment of the present invention, the memory stack structure MS includes, for example, a bottom electrode layer 310, a switching layer 320 disposed on the bottom electrode layer 310, an iridium layer 330 with a thickness of about 50 angstroms disposed on the switching layer 320, and a top electrode layer 340 disposed on the iridium layer 330, and a mask layer 350 disposed on the top electrode layer 340.

According to an embodiment of the present invention, for example, the bottom electrode layer 310 may include a TaN layer with a thickness of approximately 100-200 angstroms, but is not limited thereto. According to an embodiment of the present invention, for example, the switching layer 320 may include a TaOₓ layer 321 with a thickness of about 150-250 angstroms and a Ta₂O₅ layer 322 with a thickness of about 30-50 angstroms, but is not limited thereto. According to an embodiment of the present invention, for example, the top electrode layer 340 may include a TaN layer with a thickness of approximately 500-700 angstroms, but is not limited thereto. According to an embodiment of the present invention, for example, the mask layer 350 may include a PECVD oxide layer.

As shown in FIG. 2, an oxidation process, such as an oxygen plasma oxidation process, is then performed to form an oxidized protection layer PL on the sidewalls of the memory stack structure MS. According to an embodiment of the present invention, for example, the oxidized protection layer PL may include a TaNOₓ layer, but is not limited thereto.

As shown in FIG. 3, a deposition process and an anisotropic dry etching process are then performed to form a spacer SP around the memory stack structure MS. According to an embodiment of the present invention, the spacer SP covers the oxidized protection layer PL. According to an embodiment of the present invention, for example, the spacer SP may include silicon nitride, but is not limited thereto. During the aforementioned anisotropic dry etching process, the mask layer 350 will also be etched and shrunk, thereby exposing a portion of the upper surface 340a of the top electrode layer 340. According to an embodiment of the present invention, on the upper surface 340a, the top electrode layer 340 may include a TaNOₓ layer 340s. According to an embodiment of the present invention, the top electrode layer 340 may include a TaN layer 340t and a TaNOₓ layer 340s.

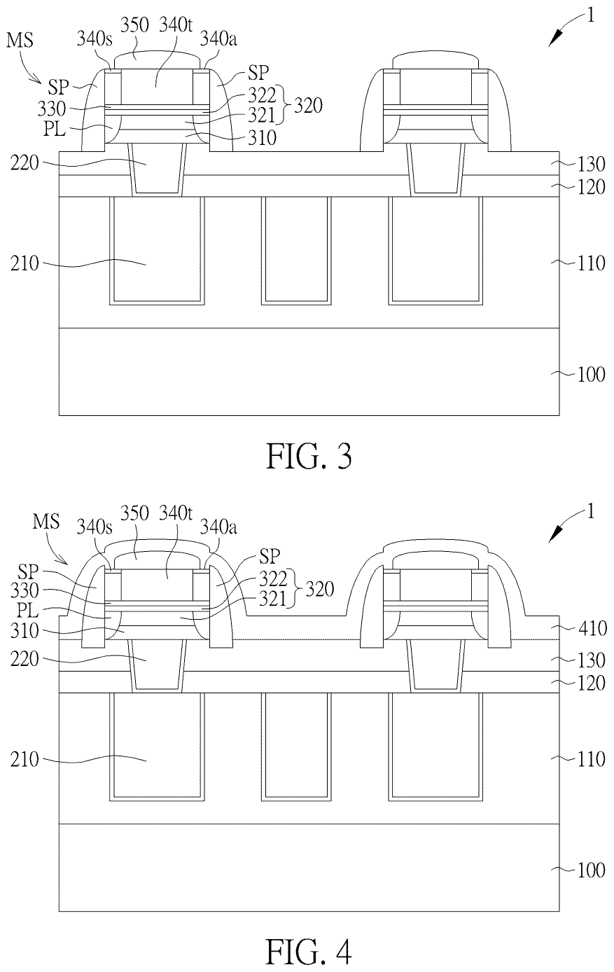

As shown in FIG. 4, a dielectric buffer layer 410 is then deposited on the substrate 100 in a blanket manner. According to an embodiment of the present invention, the dielectric buffer layer 410 may be a silicon oxide layer. According to an embodiment of the present invention, for example, the silicon oxide layer may be a PECVD oxide layer or a TEOS-based silicon oxide layer. According to an embodiment of the present invention, for example, the thickness of the dielectric buffer layer 410 may be 200-600 angstroms, but is not limited thereto. According to the embodiment of the present invention, the dielectric buffer layer 410 conformally covers the mask layer 350, the upper surface 340a of the top electrode layer 340, the spacer SP and the silicon oxide layer 130.

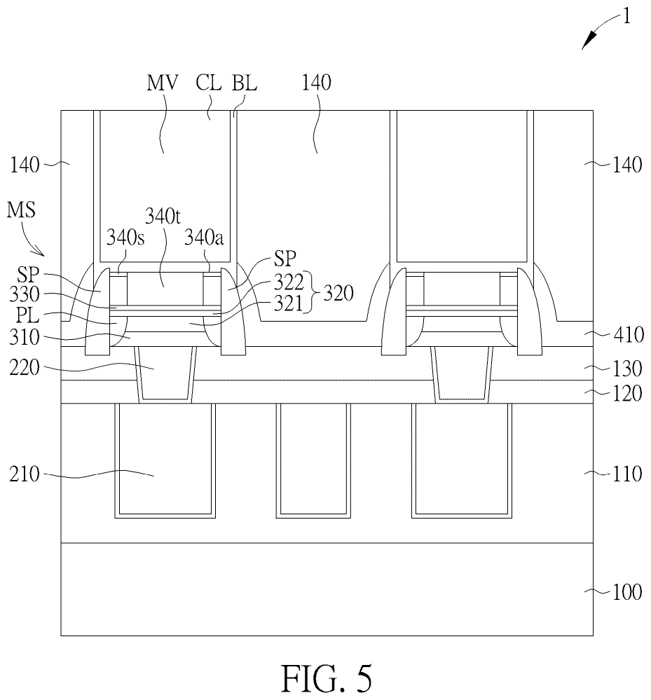

As shown in FIG. 5, next, an inter-metal dielectric (IMD) layer 140 is deposited on the substrate 100 in a blanket manner to cover the dielectric buffer layer 410. According to an embodiment of the present invention, for example, the IMD layer 140 may include a low dielectric constant material or an ultra-low dielectric constant material, with a thickness of, for example, about 1800-2200 angstroms. According to an embodiment of the present invention, a conductive via MV is then formed in the IMD layer 140 on the memory stack structure MS, so that the conductive via MV directly contacts the top electrode layer 340, the spacer SP and the dielectric buffer layer 410. Due to the protection of the spacer SP and the dielectric buffer layer 410, the memory stack structure MS can be protected from arcing damage during the plasma etching process.

According to an embodiment of the present invention, the TaNOₓ layer 340s of the top electrode layer 340 is in direct contact with the conductive via MV. According to an embodiment of the present invention, the conductive via MV includes, for example, a barrier layer BL and a copper layer CL.

Structurally, as shown in FIG. 5, the resistive memory structure 1 includes: a substrate 100 and a memory stack structure MS disposed on the substrate 100. The memory stack structure MS includes a bottom electrode layer 310, a switching layer 320 on the bottom electrode layer 310, a top electrode layer 340 on the switching layer 320, and an oxidized protection layer PL on the sidewall of the memory stack structure MS. A spacer SP is located around the memory stack structure MS. The spacer SP covers the oxidized protection layer PL. A dielectric buffer layer 410 is disposed on the spacer SP.

According to an embodiment of the present invention, the spacer SP is a silicon nitride spacer. According to an embodiment of the present invention, the switching layer 320 includes a TaOₓ layer 321 and a Ta₂O₅ layer 322. The bottom electrode layer 310 includes a TaN layer. According to an embodiment of the present invention, the memory stack structure MS may further include an iridium layer 330 located between the switching layer 320 and the top electrode layer 340.

According to an embodiment of the present invention, the resistive memory structure 1 further includes an IMD layer 140 covering the dielectric buffer layer 410. According to an embodiment of the present invention, the resistive memory structure 1 further includes: a conductive via MV, which is disposed in the IMD layer 140 on the memory stack structure MS, wherein the conductive via MV directly contacts the top electrode layer 340, the spacer SP and the dielectric buffer layer 410. According to an embodiment of the present invention, the dielectric buffer layer 410 is a silicon oxide layer, for example, a PECVD oxide layer or a TEOS-based silicon oxide layer.

According to an embodiment of the present invention, the top electrode layer 340 may include a TaN layer 340t and a TaNOₓ layer 340s, where the TaNOₓ layer 340s is in direct contact with the conductive via MV. According to an embodiment of the present invention, the conductive via MV may include a barrier layer BL and a copper layer CL.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A resistive memory structure, comprising:
a substrate;
a memory stack structure disposed on the substrate, wherein the memory stack structure comprises a bottom electrode layer, a switching layer disposed on the bottom electrode layer, a top electrode layer disposed on the switching layer, and an oxidized protection layer disposed on a sidewall of the memory stack structure;
a spacer located around the memory stack structure, wherein the spacer covers the oxidized protection layer; and
a dielectric buffer layer disposed on the spacer.

2. The resistive memory structure according to claim 1 further comprising:
an inter-metal dielectric (IMD) layer covering the dielectric buffer layer.

3. The resistive memory structure according to claim 2, further comprising:
a conductive via disposed on the memory stack structure in the IMD layer, wherein the conductive via is in direct contact with the top electrode layer, the spacer, and the dielectric buffer layer.

4. The resistive memory structure according to claim 3, wherein the top electrode layer comprises a TaN layer and a TaNOₓ layer, wherein the TaNOₓ layer is in direct contact with the conductive via.

5. The resistive memory structure according to claim 3, wherein the conductive via comprises a barrier layer and a copper layer.

6. The resistive memory structure according to claim 1, wherein the spacer is a silicon nitride spacer.

7. The resistive memory structure according to claim 1, wherein the dielectric buffer layer is a silicon oxide layer.

8. The resistive memory structure according to claim 7, wherein the silicon oxide layer is a PECVD oxide layer or a TEOS-based silicon oxide layer.

9. The resistive memory structure according to claim 1, wherein the switching layer comprises a TaOₓ layer and a Ta₂O₅ layer, and wherein the bottom electrode layer comprises a TaN layer.

10. The resistive memory structure according to claim 1, wherein the memory stack structure further comprises an iridium layer between the switching layer and the top electrode layer.

11. A method for forming a resistive memory structure, comprising:
providing a substrate;
forming a memory stack structure on the substrate, wherein the memory stack structure comprises a bottom electrode layer, a switching layer disposed on the bottom electrode layer, a top electrode layer disposed on the switching layer, and an oxidized protection layer disposed on a sidewall of the memory stack structure;
forming a spacer around the memory stack structure, wherein the spacer covers the oxidized protection layer; and
forming a dielectric buffer layer on the spacer.

12. The method according to claim 11 further comprising:
forming an inter-metal dielectric (IMD) layer covering the dielectric buffer layer.

13. The method according to claim 12, further comprising:
forming a conductive via on the memory stack structure in the IMD layer, wherein the conductive via is in direct contact with the top electrode layer, the spacer, and the dielectric buffer layer.

14. The method according to claim 13, wherein the top electrode layer comprises a TaN layer and a TaNOₓ layer, wherein the TaNOₓ layer is in direct contact with the conductive via.

15. The method according to claim 13, wherein the conductive via comprises a barrier layer and a copper layer.

16. The method according to claim 11, wherein the spacer is a silicon nitride spacer.

17. The method according to claim 11, wherein the dielectric buffer layer is a silicon oxide layer.

18. The method according to claim 17, wherein the silicon oxide layer is a PECVD oxide layer or a TEOS-based silicon oxide layer.

19. The method according to claim 11, wherein the switching layer comprises a TaOₓ layer and a Ta₂O₅ layer, and wherein the bottom electrode layer comprises a TaN layer.

20. The method according to claim 11, wherein the memory stack structure further comprises an iridium layer between the switching layer and the top electrode layer.
